(19) United States
(12) Patent Application Publication
(10) Pub. No.: US 2021/0143739 A1
(43) Pub. Date: May 13, 2021

(54) POWER CONVERSION DEVICE

(71) Applicant: AdvanOrigin Co., Ltd., Hsinchu City (TW)

(72) Inventor: Te-Hua LIU, Hsinchu City (TW)

(21) Appl. No.: 16/863,520

(22) Filed: Apr. 30, 2020

(30) Foreign Application Priority Data
Nov. 13, 2019 (TW) 108141178

(51) Int. Cl. H02M 3/158; H04B 10/80; G01R 19/165; G01J 1/44

(52) U.S. Cl. CPC H02M 3/1584; H04B 10/802; H02M 2001/0025; G01J 1/44; G01R 19/16528

(57) ABSTRACT

A power conversion device includes a switched-mode power supply (SMPS), a photocoupler and a controller. The SMPS receives a pulse width modulation (PWM) signal from the controller to generate a DC output voltage related to a DC input voltage. The photocoupler generates a reference voltage signal based on the DC output voltage. The controller adjusts at least one of a duty cycle or a frequency of the PWM signal based on the reference voltage signal.

### CROSS-REFERENCE TO RELATED APPLICATION

This application claims priority of Taiwanese Invention Patent Application No. 108141178, filed on Nov. 13, 2019.

### FIELD

The disclosure relates to a power conversion device.

### BACKGROUND

A conventional power conversion device is used to generate and output a direct current (DC) output voltage to a load (e.g., a light emitting diode module) for driving the load. However, the conventional power device lacks a simple circuit structure that can adjust the DC output voltage to maintain the DC output voltage at a desired voltage level and with a continuous waveform.

### SUMMARY

Therefore, an object of the disclosure is to provide a power conversion device that can adjust a DC output voltage thereof and that has a simple circuit structure.

According to the disclosure, the power conversion device includes a switched-mode power supply, a photocoupler, and a controller. The switched-mode power supply is disposed to receive a direct current (DC) input voltage and a pulse width modulation (PWM) signal, and has a first output terminal and a second output terminal. The switched-mode power supply is configured to generate a DC output voltage between the first and second output terminals based on the DC input voltage and the PWM signal. The photocoupler is coupled to the first and second output terminals of the switched-mode power supply for receiving the DC output voltage therefrom, and is configured to generate a reference voltage signal based on the DC output voltage. The photocoupler includes a first resistor, a light emitting diode, a second resistor and a phototransistor. The first resistor and the light emitting diode are coupled in series between the first and second output terminals of the switched-mode power supply. The second resistor has a first terminal providing the reference voltage signal, and a second terminal. The phototransistor is disposed to receive light emitted by the light emitting diode, and has a first terminal, and a second terminal coupled to the first terminal of the second resistor. The controller is coupled to the first terminal of the second resistor for receiving the reference voltage signal therefrom, and is coupled to the switched-mode power supply. The controller is configured to generate the PWM signal, and to adjust at least one of a frequency or a duty cycle of the PWM signal based on a relationship between the reference voltage and a predetermined voltage value.

### BRIEF DESCRIPTION OF THE DRAWINGS

Other features and advantages of the disclosure will become apparent in the following detailed description of the embodiment (s) with reference to the accompanying drawings, of which:

FIG. 1 is a schematic circuit diagram illustrating a first embodiment of a power conversion device according to the disclosure; and

FIG. 2 is a schematic circuit diagram illustrating a second embodiment of a power conversion device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

Referring to FIG. 1, a first embodiment of a power conversion device according to this disclosure is configured to receive a DC input voltage V_{IN}, and converts the DC input voltage V_{IN} into a DC output voltage N_{OUT}, that is provided to a load (not shown), which can be exemplified as a light emitting diode module. In this embodiment, the DC input voltage V_{IN} is provided by a power supply (not shown) which may be a battery, and is between, for example, 3.6 V and 5.5 V.

In the first embodiment, the power conversion device includes a switched-mode power supply 1, a photocoupler 2, a capacitor 3 and a controller 4.

The switched-mode power supply 1 is disposed to receive the DC input voltage Y_{IN} between a first voltage node and ground and to receive a pulse width modulation (PWM) signal, and has a first output terminal Q₁ and a second output terminal Q₂. The switched-mode power supply 1 is configured to generate the DC output voltage

V_{OUT} between the first output terminal Q₁ and the second output terminal Q₂ based on the DC input voltage Y_{IN} and the PWM signal. In this embodiment, the switched-mode power supply 1 includes a diode 11, a transistor 12, an inductor 13 and a capacitor 14.

The diode 11 has a cathode disposed to receive the DC input voltage Y_{IN} and an anode coupled to the second output terminal Q₂. The transistor 12 has a first terminal coupled to the anode of the diode 11, a grounded second terminal, and a control terminal coupled to the controller 4 for receiving the PWM signal therefrom. The inductor 13 is coupled between the cathode of the diode 11 and the first output terminal The capacitor 14 is coupled between the first output terminal Q₁ and the second output terminal Q₂, and a voltage across the capacitor 14 is the DC output voltage V_{OUT}. In this embodiment, the transistor 12 is an N-type metal-oxide-semiconductor field-effect transistor (MOSFET) that has a drain terminal, a source terminal and a gate terminal serving as the first terminal, the second terminal and the control terminal of the transistor 12, respectively, but this disclosure is not limited thereto. For example, an insulated gate bipolar transistor (IGBT) may be used as the transistor 12 in other embodiments.

The photocoupler 2 is coupled to the first and second output terminals Q₁, Q₇ of the switched-mode power supply 1 for receiving the DC output voltage V_{OUT} therefrom, and is configured to generate a reference voltage signal based on the DC output voltage V_{OUT}. In this embodiment, the photocoupler 2 includes a first resistor 21, a light emitting diode 22, a second resistor 23 and a phototransistor 24.

The first resistor 21 and the light emitting diode 22 are coupled in series between the first and second output terminals Q₁, Q₂ of the switched-mode power supply 1. The first resistor 21 is coupled to one of the first and second output terminals Q₁, Q₂, and the light emitting diode 22 is coupled to the other one of the first and second output terminals Q1, Q7. In this embodiment, the first resistor 21 is coupled to the first output terminal Q1, and the light emitting diode 22 is coupled to the second output terminal Q7. In other embodiments, the first resistor 21 can be coupled to the second output terminal Q2, and the light emitting diode 22 can be coupled to the first output terminal Q1.

The second resistor 23 has a first terminal providing the reference voltage signal, and a second terminal. The phototransistor 24 is disposed to receive light emitted by the light emitting diode 22, and has a first terminal coupled to the first voltage node for receiving the DC input voltage V_{IN} therefrom, and a second terminal coupled to the first terminal of the second resistor 23. The second terminal of the second resistor 23 is coupled to one of ground and the first voltage node, and the first terminal of the phototransistor 24 is coupled to the other one of ground and the first voltage node. In this embodiment, the second terminal of the second resistor 23 is grounded, and the first terminal of the phototransistor 24 is coupled to the first voltage node. In other embodiments, the second terminal of the second resistor 23 can be coupled to the first voltage node, and the first terminal of the phototransistor 24 can be grounded.

The capacitor 3 has a first terminal coupled to the first voltage node, and a grounded second terminal, and is used to stabilize the voltage provided into the power conversion device.

The controller 4 is coupled to the first terminal of the second resistor 23 for receiving the reference voltage signal therefrom, and is coupled to the switched-mode power supply 1. In this embodiment, the controller 4 has a first pin “Vcc” coupled to the first voltage node for receiving the DC input voltage V_{IN} that serves as a working voltage required by the controller 4, a second pin “Vil” coupled to the first terminal of the second resistor 23 for receiving the reference voltage signal therefrom, a third pin “GND” coupled to ground, and a fourth pin “PWM” coupled to the control terminal of the transistor 12 for providing the PWM signal thereto. The controller 4 is configured to generate the PWM signal, and to adjust at least one of a frequency or a duty cycle of the PWM signal (i.e., one or both of the frequency and the duty cycle of the PWM signal) based on the DC input voltage V_{IN}, and a relationship between the reference voltage signal and a predetermined voltage value.

In one embodiment, the controller 4 may calculate a current magnitude of the DC output voltage V_{OUT} based on the reference voltage signal, so as to determine a difference between the current magnitude of the DC output voltage V_{OUT} and a desired magnitude for the DC output voltage V_{OUT}. In such an implementation, the desired magnitude of the DC output voltage V_{OUT} may serve as the predetermined voltage value. Then, the controller 4 can adjust the frequency and/or the duty cycle of the PWM signal based in the DC input voltage V_{IN} and the difference between the current magnitude and the desired magnitude of the DC output voltage V_{OUT}.

In one embodiment, the controller 4 may compare the reference voltage signal that represents the current magnitude of the DC output voltage V_{OUT} with the predetermined voltage value that represents the desired magnitude of the DC output voltage V_{OUT}. For instance, the controller 4 may increase the duty cycle of the PWM signal to raise the DC output voltage V_{OUT} when a voltage magnitude of the reference voltage signal is smaller than the predetermined voltage value, and decrease the duty cycle of the PWM signal to reduce the DC output voltage V_{OUT} when the voltage magnitude of the reference voltage signal is greater than the predetermined voltage value. Since the DC output voltage V_{OUT} will change with variation of the frequency of the PWM signal, the controller 4 may raise or reduce the DC output voltage T_{OUT} by increasing or decreasing the frequency of the PWM signal. In addition, the controller 4 may be configured to not change the frequency and the duty cycle of the PWM signal when the voltage magnitude of the reference voltage signal is equal to the predetermined voltage value or falls within a tolerance range with respect to the predetermined voltage value.

In a case that the power conversion device is configured to continuously output large current, and that a current flowing through the transistor 12 when the transistor 12 is conducting is assumed to be equal to an output current of the power conversion device, the following relationships can be obtained:

$$\begin{matrix}D = \frac{{T}_{on}}{T} = \frac{{V}_{out}}{{V}_{in}} & ( 1 ) \\ f = \frac{2 \times {V}_{out} \times ( 1 - {V}_{out} \text{/} {V}_{in} )}{L \times {I}_{out}} & ( 2 )\end{matrix}$$

where D represents the duty cycle of the PWM signal, Tₒₙ represents a length of time during which the transistor 12 conducts within a period of the PWM signal, Tₒₙ represents the period of the PWM signal represents a magnitude of the DC input voltage V_{IN}, f represents the frequency of the PWM signal, L represents an inductance of the inductor 13, and Iₒᵤₜ represents a magnitude of the output current of the power conversion device. According to equations (1) and (2), the controller 4 can control the duty cycle and the frequency of the PWM signal such that the output current of the power conversion device does not exceed an upper current limit, preventing the load of the power conversion device from burning out.

Referring to FIG. 2, a second embodiment of a power conversion device according to this disclosure is similar to the first embodiment, and differs from the first embodiment in that: 1) the DC input voltage V_{IN} may be, for example, between 100 V and 240 V; 2) the power conversion device further includes a voltage divider 5, a voltage regulator 6 and a capacitor 7, and the controller 4 is further coupled to the voltage divider 5 and the voltage regulator 6; 3) the first pin “Vcc” of the controller 4 and the first terminal of the phototransistor 24 do not directly receive the DC input voltage V_{IN} (i.e., are not directly coupled to the first voltage node); and 4) the inductor 13 is coupled between the anode of the diode 11 and the second output terminal Q₂ (although the inductor 13 can be coupled between the cathode of the diode 11 and the first output terminal Q₁, as with the first embodiment). In this embodiment, the DC input voltage V_{IN} may be generated by using a bridge rectifier (not shown) that rectifies an alternating current (AC) voltage signal generated by an AC voltage source (not shown).

The voltage divider 5 is disposed to receive the DC input voltage V_{IN}, and is configured to generate a division voltage based on the DC input voltage V_{IN}. In this embodiment, the voltage divider 5 includes a third resistor 51, a fourth resistor 52 and a capacitor 53. The third resistor 51 has a first terminal disposed to receive the DC input voltage V_{IN}, and a second terminal coupled to the controller 4. The fourth resistor 52 has a first terminal coupled to the second terminal of the third resistor 51, and a grounded second terminal. The capacitor 53 is coupled between the first and second terminals of the fourth resistor 52. The division voltage is provided at the first terminal of the fourth resistor 52.

The voltage regulator 6 has an input terminal disposed to receive the DC input voltage V_{IN}, and an output terminal, and is configured to generate a regulated voltage at the output terminal thereof based on the DC input voltage V_{IN}.

The capacitor 7 is coupled between the output terminal of the voltage regulator 6 and ground.

In this embodiment, the controller 4 further includes a fifth pin “Vol” and a sixth pin “Vi2”. The first pin “Vcc” is coupled to the voltage regulator 6 for receiving the regulated voltage therefrom for the controller 4 to generate a voltage output for the photocoupler 2 at the fifth pin “Vol” based on the regulated voltage. The sixth pin “Vi2” is coupled to the first terminal of the fourth resistor 52 for receiving the division voltage therefrom for the controller 4 to acquire the magnitude of the DC input voltage V_{IN}, so that the controller 4 can adjust the frequency and/or the duty cycle of the PWM signal based on the magnitude of the DC input voltage V_{IN} acquired from the division voltage, and the relationship between the reference voltage signal and the predetermined voltage value. For example, the magnitude of the DC input voltage V_{IN} is calculated according to:

$${V}_{i n} = A \times {V}_{d} \times \frac{( {R}_{51} + {R}_{52} )}{{R}_{52}}$$

where Vᵢₙ represents the magnitude of the DC input voltage V_{IN}, A is a predetermined constant, V_{d} represents a magnitude of the division voltage, R₅₁ represents a resistance of the third resistor 51, and R₅₇ represents a resistance of the fourth resistor 52.

Because of the capacitor 3, the division voltage would be related to a peak voltage of the DC input voltage V_{IN} generated by the bridge rectifier, so the predetermined constant A can be set as 0.707 to obtain a root-mean-square value of the peak voltage to serve as the DC input voltage V.

The second terminal of the second resistor 23 is coupled to one of ground and the fifth pin “Vol” of the controller 4 that provides the voltage output, and the first terminal of the phototransistor 24 is coupled to the other one of ground and the fifth pin “Vol” of the controller 4. It is noted that, since the voltage regulator 6 is usually a high-voltage regulator that may heat up easily, it can provide only a small amount of current. Therefore, the voltage regulator 6 provides the regulated voltage for the controller 4 to output the current flowing through the phototransistor 24 and the second resistor 23 at the fifth pin “Vol” of the controller 4 in this embodiment. In a case that the voltage regulator 6 is capable of providing sufficient current, the serially-connected phototransistor 24 and second resistor 23 may be directly coupled to the voltage regulator 6 (i.e., at the first pin “Vcc” of the controller 4) for receiving the regulated voltage via the second terminal of the second resistor 23 or the first terminal of the phototransistor 24. In this embodiment, the second terminal of the second resistor is grounded, and the first terminal of the phototransistor 24 is coupled to the fifth pin “Vol” of the controller 4 for receiving the voltage output therefrom. In other embodiments, the second terminal of the second resistor 23 may be coupled to the fifth pin “Vol” of the controller 4 for receiving the voltage output therefrom, in which case the first terminal of the phototransistor 24 is grounded.

The operation of the second embodiment is similar to that of the first embodiment, so details thereof are not repeated herein for the sake of brevity.

To sum up, the power conversion device of this disclosure uses the photocoupler 2 to continuously generate the reference voltage signal, so that the controller 4 can continuously adjust the DC output voltage V_{OUT}. In addition, the simple circuit structure of the power conversion device according to this disclosure may be advantageous for being low cost.

In the description above, for the purposes of explanation, numerous specific details have been set forth in order to provide a thorough understanding of the embodiment(s). It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure. While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A power conversion device, comprising:
a switched-mode power supply disposed to receive a direct current (DC) input voltage and a pulse width modulation (PWM) signal, and having a first output terminal and a second output terminal, said switched-mode power supply configured to generate a DC output voltage between said first and second output terminals based on the DC input voltage and the PWM signal;
a photocoupler coupled to said first and second output terminals of said switched-mode power supply for receiving the DC output voltage therefrom, and configured to generate a reference voltage signal based on the DC output voltage, said photocoupler including:
a first resistor and a light emitting diode coupled in series between said first and second output terminals of said switched-mode power supply;
a second resistor having a first terminal that provides the reference voltage signal, and a second terminal; and
a phototransistor disposed to receive light emitted by said light emitting diode, and having a first terminal, and a second terminal that is coupled to said first terminal of said second resistor; and
a controller coupled to said first terminal of said second resistor for receiving the reference voltage signal therefrom, and coupled to said switched-mode power supply, said controller configured to generate the PWM signal, and to adjust at least one of a frequency or a duty cycle of the PWM signal based on a relationship between the reference voltage and a predetermined voltage value.

2. The power conversion device of claim 1, further comprising:
a capacitor having a first terminal that is disposed to receive the DC input voltage, and a grounded second terminal;
wherein said controller is configured to adjust at least one of the frequency or the duty cycle of the PWM signal further based on the DC input voltage.

3. The power conversion device of claim 1, wherein said first resistor is coupled to one of said first and second output terminals, and said light emitting diode is coupled to the other one of said first and second output terminals.

4. The power conversion device of claim 3, wherein said second terminal of said second resistor is coupled to one of ground and a node of the power conversion device that receives the DC input voltage, and said first terminal of said phototransistor is coupled to the other one of ground and said node.

5. The power conversion device of claim 1, wherein said switched-mode power supply includes:
a diode having a cathode that is disposed to receive the DC input voltage, and an anode that is coupled to said second output terminal;
a transistor having a first terminal that is coupled to said anode of said diode, a grounded second terminal, and a control terminal that is coupled to said controller for receiving the PWM signal therefrom;
a capacitor coupled between said first and second output terminals, wherein a voltage across said capacitor is the DC output voltage; and
an inductor coupled between said diode and one of said first and second output terminals.

6. The power conversion device of claim 5, wherein said inductor is coupled in one of a first configuration and a second configuration;
wherein said inductor is coupled between said cathode of said diode and said first output terminal in the first configuration; and
wherein said inductor is coupled between said anode of said diode and said second output terminal in the second configuration.

7. The power conversion device of claim 1, further comprising:
a voltage divider disposed to receive the DC input voltage, and configured to generate a division voltage based on the DC input voltage;
a voltage regulator having an input terminal that is disposed to receive the DC input voltage, and an output terminal, and configured to generate a regulated voltage at said output terminal thereof based on the DC input voltage; and
a capacitor coupled between said output terminal of said voltage regulator and ground;
wherein said controller is further coupled to said voltage divider and said output terminal of said voltage regulator for receiving the division voltage and the regulated voltage respectively therefrom, and configured to adjust at least one of the frequency or the duty cycle of the PWM signal further based on the division voltage.

8. The voltage conversion device of claim 7, wherein said voltage divider includes:
a third resistor having a first terminal that is disposed to receive the DC input voltage, and a second terminal that is coupled to said controller;
a fourth resistor having a first terminal that is coupled to said second terminal of said third resistor, and a grounded second terminal; and
a capacitor coupled between said first and second terminals of said fourth resistor;
wherein the division voltage is provided at said first terminal of said fourth resistor.

9. The power conversion device of claim 7, wherein said controller is configured to generate a voltage output for said photocoupler based on the regulated voltage.

10. The power conversion device of claim 9, wherein said second terminal of said second resistor is coupled to one of ground, a first node of said power conversion device that receives the voltage output generated by said controller, and a second node of said power conversion device that receives the regulated voltage; and
wherein said first terminal of said phototransistor is coupled to ground when said second terminal of said second resistor is coupled to one of said first node and said second node of said power conversion device, and is coupled to one of said first node and said second node of said power conversion device when said second terminal of said second resistor is coupled to ground.
